(19) United States
(12) Patent Application Publication
(10) Pub. No.: US 2007/0145472 A1
(43) Pub. Date: Jun. 28, 2007

(54) FLASH MEMORY CELL INCLUDING DUAL TUNNEL OXIDE LAYER AND METHOD OF MANUFACTURING THE SAME

(76) Inventor: Cheol Sang Kwak, Gyeonsangbuk-do (KR)

Correspondence Address: SHERR & NOURSE, PLLC, 620 HERNDON PARKWAY, SUITE 200, HERNDON, VA, 20170, US

(21) Appl. No.: 11/613,096

(22) Filed: Dec. 19, 2006

(30) Foreign Application Priority Data
Dec. 26, 2005 (KR) 10-2005-0129758

(51) Int. Cl. H01L 29/788; H01L 29/792; H01L 21/336

(52) U.S. Cl. 257/321; 438/261; 438/264; 438/287; 257/324

(57) ABSTRACT

A flash memory cell may include a tunnel oxide layer over a semiconductor substrate with a first tunnel having a first thickness and a second tunnel having a second thickness. A charge storage layer may be formed over a tunnel oxide layer, an insulating layer may be formed over a charge storage layer, and/or a control gate may be formed over an insulating layer. A control gate may be supplied with driving power. A first thickness of a first tunnel may be less than a second thickness of a second tunnel.

The present application claims priority under 35 U.S.C. 119 and 35 U.S.C. 365 to Korean Patent Application No. 10-2005-0129758 (filed on Dec. 26, 2005), which is hereby incorporated by reference in its entirety.

### BACKGROUND

Flash memory may be a nonvolatile semiconductor memory that may utilize an erasable programmable read only memory (EPROM) and/or an erasing method of an electrically erasable programmable read only memory (EEPROM). Flash memory may include flash EEPROM. Flash memory may retain stored information when power is turned off and may also freely input and output the information. Accordingly, flash memory may be advantageous for use with digital televisions, digital camcorders, mobile phones, digital cameras, personal digital assistants, game consoles, and/or similar devices.

One type of flash memory is stack gate type flash memory. Another type of flash memory is split gate type flash memory. The type of flash memory may be based on a flash memory cell structure. A stack gate type flash memory has a floating gate (e.g. which stores electric charges) and a control gate (e.g. to which driving power is applied) that are stacked.

FIG. 1 schematically illustrates a unit cell of an stack gate type flash memory. As illustrated in FIG. 1, isolation layers (not shown) that may define an active device region may be formed over semiconductor substrate 10 in a bit line direction. Tunnel oxide layer 20, floating gate 22, inter-gate insulating layer 24, and/or control gate 26 may be sequentially formed over an active device region between neighboring isolation layers. Source and drain diffusion regions 14 may be formed in semiconductor substrate 10. Source and drain diffusion regions 14 may be separated from each other by a channel region under floating gate 22.

A unit cell of a stack gate type flash memory may be programmed by injecting drain electrons into a floating gate in a channel hot electron injection mode. A unit cell of a stack gate type flash memory may be erased by emitting electrons confined in the floating gate through a Fowler-Nordheim (FN) tunneling mechanism.

FIG. 2 illustrates a gate voltage V_{G}-current I_{d} characteristics of an example NOR type flash memory cell. In an erased state, a floating gate has excessive holes. When a floating gate has excessive holes, the characteristic of a transistor may be in depletion (for example, as illustrated in curve (a) of FIG. 2). When a transistor is in a channel-enhancement mode (for example, as illustrated in curve (b) of FIG. 2), threshold value of a selection transistor may be at approximately 1 V. When a transistor is in a programmed state, electrons may be injected into a floating gate and the threshold voltage of the floating gate transistor may be approximately about 7 V (for example, as illustrated in curve (c) of FIG. 2).

The flash memory cell illustrated in FIG. 1 may only be able to store 1-bit of information. If the flash memory cell capable of storing information of at least two bits in one unit cell can be formed, it can improve at least twice as high memory integration density as the conventional flash memory cell.

### SUMMARY

Embodiments relate to a multi-bit flash memory cell that may store at least two bits of information in a single memory cell and/or a method of manufacturing the same. In embodiments, a multi-bit flash memory cell may include a dual tunnel oxide layer that may be driven by at least two different programming and erasing voltages.

In embodiments, a flash memory cell may include a tunnel oxide layer over a semiconductor substrate with a first tunnel having a first thickness and a second tunnel having a second thickness. In embodiments, a charge storage layer may be formed over a tunnel oxide layer, an insulating layer may be formed over a charge storage layer, and/or a control gate may be formed over an insulating layer. A control gate may be supplied with driving power. A first thickness of a first tunnel may be less than a second thickness of a second tunnel.

Embodiments relate to a method of manufacturing a flash memory cell. In embodiments, a method may include at least one of: forming a first tunnel oxide layer over an active device region of a semiconductor substrate which is defined by at least two isolation layers; removing a portion of a first tunnel oxide layer by photolithography and/or etching processes; forming a second tunnel oxide layer over an active device region of a semiconductor substrate; forming a charge storage layer over first and second tunnel oxide layers; forming an insulating layer over a charge storage layer; and/or forming a control gate over an insulating layer.

### BRIEF DESCRIPTION OF DRAWINGS

FIG. 1 is a sectional view of a stack gate type flash memory cell.

FIG. 2 is a graph showing voltage-current characteristics of a stack gate type flash memory cell.

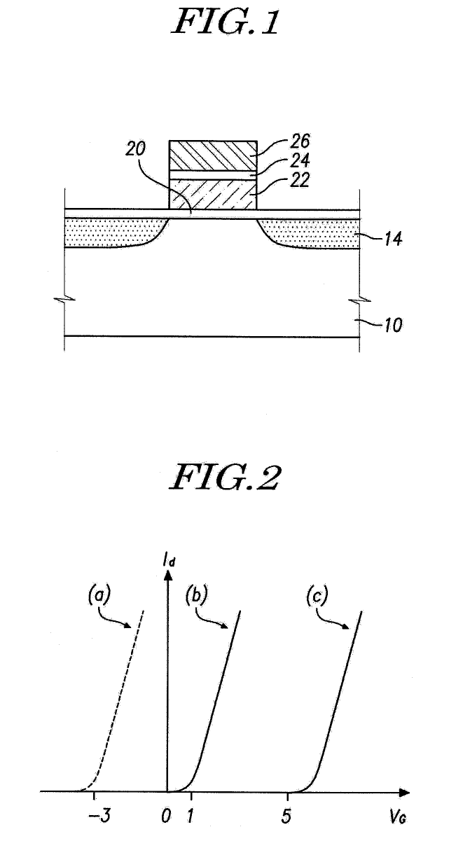

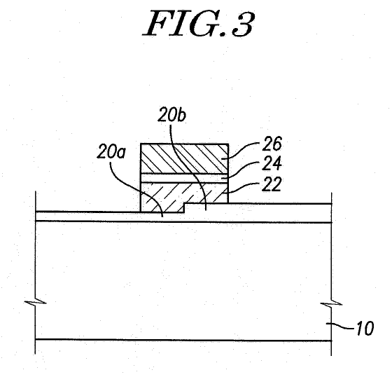

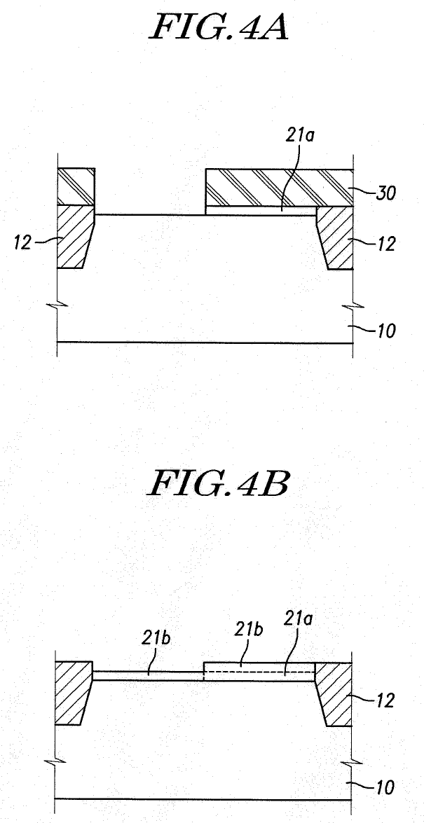

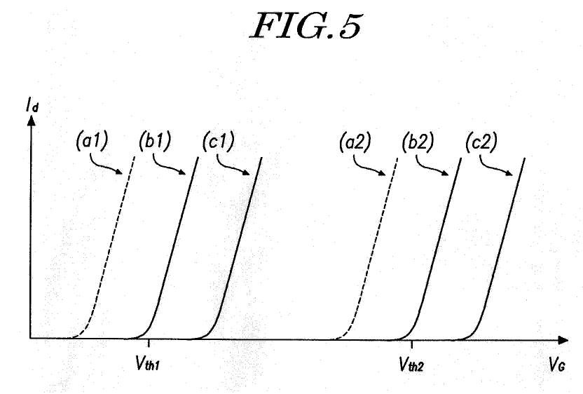

Example FIG. 3 is a sectional view of a flash memory cell including a dual tunnel oxide layer, according to embodiments.

Example FIGS. 4A and 4B are sectional views illustrating a method of manufacturing a flash memory cell, according to embodiments.

Example FIG. 5 is a graph showing voltage-current characteristics of a flash memory cell, according to embodiments.

### DETAILED DESCRIPTION

In embodiments, a flash memory cell may include a dual tunnel oxide layer. Example FIG. 3 is a schematic sectional view illustrating a flash memory cell, according to embodiments. As illustrated in FIG. 3, a flash memory cell may includes a dual oxide layer formed over semiconductor substrate 10. A duel oxide layer have include first tunnel 20a having a first thickness and second tunnel 20b having a second thickness. The thickness of first tunnel 20a may be less than the thickness of second tunnel 20b.

Charge storage layer 22 may be formed over first tunnel 20a and second tunnel 20b. Charge storage layer 22 may be formed of polysilicon. A flash memory cell may be a stack gate type flash memory cell. A flash memory cell may have a 2-poly gate structure. A flash memory cell may include a floating gate and a control gate. In embodiments, charge storage layer 22 may include silicon nitride.

In embodiments, a flash memory cell may include a silicon-oxide-nitride-oxide-silicon (SONOS) dielectric layer together with a tunnel oxide layer and insulating layer 24. A gate of a flash memory cell having a SONOS structure may have a relatively low height. A gate having a relatively low height may allow for a semiconductor device to be more highly integrated and/or operate at a relatively low operating voltage. In embodiments, charge storage layer 22 may cover first tunnel 20a and second tunnel 20b of the tunnel oxide layer in substantially the same area. Charge storage layer 22 covering first tunnel 20a and second tunnel 20b may provide relatively stable operation of a flash memory cell.

Insulating layer 24 may be formed over charge storage layer 22. Control gate 26 may be formed over insulating layer 22. Insulating layer 24 may insulate control gate 26 from charge storage layer 22. A driving voltage may be applied to control gate 26 to drive a flash memory cell.

A flash memory cell illustrated in FIG. 3 may include a dual tunnel oxide layer. A dual tunnel oxide layer may include a first tunnel 20a and a second tunnel 20b. First tunnel 20a and second tunnel 20b may have different thicknesses in the same cell structure. Different thicknesses of first tunnel 20a and second tunnel 20b may allow for storage of two bits of information in a single cell structure.

Example FIG. 5 illustrates example gate voltage V_{G}-current I_{d} characteristics of a 2-bit flash memory cell, in accordance with embodiments. In FIG. 5, an erase state of a flash memory cell in first tunnel 20a region is illustrated by curse (a1) as the basis of initial voltage Vₜₕ₁. A program state of a flash memory cell in first tunnel 20a region is illustrated by curve (c1) as the basis of initial voltage Vₜₕ₁. Curve (b1) illustrates characteristics of a flash memory cell in an initial state for first tunnel 20a region.

Erase and program states of the flash memory cell in a second tunnel 20b region are different than erase and program sates in first tunnel region 20a. In embodiments, erase and program states in first tunnel region 20a and second tunnel region 20b are different because second tunnel region 20b is thicker than first tunnel 20a. An erase state of a flash memory cell in second tunnel 20b region is illustrated by curse (a2) as the basis of initial voltage Vₜₕ₂. A program state of a flash memory cell in second tunnel 20b region is illustrated by curve (c2) as the basis of initial voltage Vₜₕ₂. Curve (b2) illustrates characteristics of a flash memory cell in an initial state for second tunnel 20b region.

According to embodiments, a 2-bit flash memory cell may be appreciated with voltage-current characteristics in which program and erase states are different from each other at first tunnel 20a and second tunnel 20b. In embodiments, two bits of data may be stored in a single flash memory cell.

Example FIGS. 4A and 4B illustrate methods of manufacturing a flash memory cell including a dual tunnel oxide layer, according to embodiments. Isolation layers 12 (e.g. shallow trench isolation (STI) layers) may define an active device region in substrate 10. A surface of substrate 10 may be oxidized in a defined active device region. In embodiments, oxidation is performed by thermal oxidation.

Photoresist pattern 30 may be formed over an oxidized surface of substrate 10. A portion of an oxide layer formed by oxidization of substrate 10 may be etched using photoresist pattern 30 as an etch mask. In embodiments, an oxide layer may be etched by wet etching. Wet etching may prevent damage to substrate 10. After an etching process, oxide layer 21a may remain. Photoresist pattern 30 may be stripped.

As illustrated in FIG. 4B, an active device region of substrate 10 may be oxidized to form oxide layer 21b, according to embodiments. In embodiments, a two-step oxide layer forming process may be performed. As illustrated in FIG. 4B, one area of an oxide layer has only second oxide layer 21b, while another area of the oxide layer has both first oxide layer 21a and second oxide layer 21b. In embodiments, an area of an oxide layer with both first oxide layer 21a and second oxide layer 21b (e.g. tunnel 20b) is thicker than an area of an oxide layer with only second oxide layer 21b (e.g. tunnel 20a).

As illustrated in FIG. 3, charge storage layer 22 may be formed over first tunnel 20a and second tunnel 20b. Insulating layer 24 may be formed over charge storage layer 22. Control gate 26 may be formed over insulating layer 24.

In embodiments, a multi-bit flash memory cell structure may be capable of storing at least two bits of information in a single cell. Flash memory devices with cells that can store multiple bits of information may be formed to have a higher memory integration density than flash memory devices with cells that can only store a single bit of information. In embodiments, a flash memory device with relatively high memory integration density (e.g. twice the integration of cells that store a single bit of information) may provide for a relatively high chip integration density in a semiconductor device. In embodiments, memory cells having a dual tunnel oxide layer may be able to perform higher level functions compared to memory cells that do not have a dual tunnel oxide layer.

While the invention has been shown and described with reference to certain preferred embodiments thereof, it will be understood by those skilled in the art that various changes in form and details may be made therein without departing from the spirit and scope of the invention as defined by the appended claims.

What is claimed:

1. A semiconductor device comprising a tunnel oxide layer including formed over a semiconductor substrate, wherein:
the tunnel oxide layer comprises a first tunnel and a second tunnel;
the first tunnel is thicker than the second tunnel.

2. The semiconductor device of claim 1, comprising a charge storage layer formed over the tunnel oxide layer.

3. The semiconductor device of claim 2, wherein:
the first tunnel and the second tunnel are adjacent to each other; and
the charge storage layer covers the first tunnel and the second tunnel.

4. The semiconductor device of claim 2, wherein the charge storage layer comprises polysilicon.

5. The semiconductor device of claim 2, wherein the charge storage layer a 2-poly gate structure together with a control gate.

6. The semiconductor device of claim 2, wherein the charge storage layer comprises silicon nitride.

7. The semiconductor device of claim 2, wherein the charge storage layer has a silicon-oxide-nitride-oxide-silicon (SONOS) dielectric layer structure together with the tunnel oxide layer and an insulating layer.

8. The semiconductor device of claim 2, comprising:
an insulating layer formed over the charge storage layer; and
a control gate formed over the insulating layer.

9. A method comprising:
forming a first tunnel oxide layer over a semiconductor substrate;
etching a portion of the first tunnel oxide layer in a first area;
forming a second tunnel oxide layer over the semiconductor substrate in the first area and in a second area, wherein the second area includes an unetched portion of the first tunnel oxide layer.

10. The method of claim 9, wherein:
a first tunnel is formed in the first area comprising a first portion of the second tunnel oxide layer;
a second tunnel is formed in the second area comprising a second portion of the second tunnel oxide layer and the first tunnel oxide layer.

11. The method of claim 10, wherein the second tunnel is thicker than the first tunnel.

12. The method of claim 9, comprising forming a charge storage layer over the first tunnel oxide layer and the second tunnel oxide layer.

13. The method of claim 12, wherein the charge storage layer covers the first tunnel oxide layer and the second tunnel oxide layer in approximately the same area.

14. The method of claim 12, wherein the charge storage layer comprises polysilicon.

15. The method of claim 12, wherein the charge storage layer comprises silicon nitride.

16. The method of claim 12, comprising forming an insulating layer over the charge storage layer.

17. The method of claim 16, comprising forming a control gate over the insulating layer.

18. The method of claim 9, wherein the first area and the second area are over an active device region of the semiconductor substrate, wherein the active device region is between at least two isolation layers.

19. The method of claim 9, wherein the charge storage layer is formed of polysilicon.

20. The method of claim 9, wherein the charge storage layer is formed of silicon nitride.
